(19) United States
(12) Patent Application Publication
(10) Pub. No.: US 2021/0156885 A1
(43) Pub. Date: May 27, 2021

(54) PROBE

(71) Applicant: Kabushiki Kaisha Nihon Micronics, Tokyo (JP)

(72) Inventors: Akihiro SHUTO, Oita (JP); Ryuichi UMEDA, Oita (JP)

(21) Appl. No.: 16/950,721

(22) Filed: Nov. 17, 2020

(30) Foreign Application Priority Data
Nov. 27, 2019 (JP) 2019-213959

(51) Int. Cl. G01R 1/067; H01R 13/24

(52) U.S. Cl. CPC G01R 1/06722; H01R 13/2421

(57) ABSTRACT

A probe includes: a tubular barrel; a first plunger that has a proximal end portion inserted from one opening end of the barrel and slides along an axial direction of the barrel in a state in which a distal end is exposed; and a coil spring that is disposed inside the barrel and urges the first plunger in the axial direction of the barrel. The proximal end portion of the first plunger includes: an insertion portion that extends inside the coil spring from one end of the coil spring; and a head portion that is coupled to the insertion portion, has an outer diameter larger than an outer diameter of the coil spring, and abuts against the one end of the coil spring.

### CROSS-REFERENCE TO PRIORITY APPLICATION

This application is based upon and claims the benefit of priority from prior Japanese Patent Application P2019-213959, filed on Nov. 27, 2019; the entire contents of which are incorporated by reference herein.

### TECHNICAL FIELD

Embodiments described herein relate generally to a probe for use in measuring characteristics of an object to be tested.

### BACKGROUND

A probe is used for measuring characteristics of an object to be tested such as an integrated circuit in a wafer state. In the measurement using the probe, one end portion of the probe is brought into contact with an electrode of the object to be tested, and other end portion of the probe is brought into contact with a terminal arranged on a printed board (hereinafter, this terminal will be referred to as “land”). The land is electrically connected to a tester.

For the probe, used is such a configuration in which a part of a plunger with a small diameter, which contacts the object to be tested, is inserted into a tubular barrel with a large diameter. For example, the plunger is urged by a coil spring disposed inside the barrel, and the probe is brought into contact with the object to be tested with a predetermined stylus pressure.

A pitch of arranged electrodes of the object to be tested is narrowed, and the number of the electrodes is increased, whereby a diameter of the probe is reduced, and the number of pins thereof is increased. Therefore, an outer diameter of the probe is reduced, and following this, it is necessary to reduce a wire diameter of the coil spring. However, the coil spring becomes more likely to meander as the wire diameter is smaller, and the coil spring contacts an inner wall surface of the barrel. As a result, the barrel and the coil spring are damaged.

### BRIEF SUMMARY

In accordance with an aspect of the present disclosure, there is provided a probe including: a tubular barrel; a first plunger that has a proximal end portion inserted from one opening end of the barrel and slides along an axial direction of the barrel; and a coil spring that is disposed inside the barrel and urges the first plunger in the axial direction of the barrel. The proximal end portion of the first plunger includes: an insertion portion that extends inside the coil spring from one end of the coil spring; and a head portion that is coupled to the insertion portion, has an outer diameter larger than an outer diameter of the coil spring, and abuts against the one end of the coil spring.

### BRIEF DESCRIPTION OF THE DRAWINGS

FIG. 1 is a schematic view illustrating a configuration of a probe according to an embodiment.

FIG. 2 is a schematic view explaining a holding method of the probe according to the embodiment.

FIG. 3 is a schematic view illustrating a holding state of the probe at a time of measurement (No. 1).

FIG. 4 is a schematic view illustrating the holding state of the probe at the time of measurement (No. 2).

FIG. 5 is a schematic view illustrating a configuration of a probe of a comparative example.

FIG. 6 is a schematic view illustrating a state of a coil spring of the probe of the comparative example at a time of measurement.

FIG. 7 is a schematic view illustrating a state of a coil spring of the probe according to the embodiment at the time of measurement.

FIG. 8 is a schematic view for explaining diameters of respective portions of the probe according to the embodiment.

### DETAILED DESCRIPTION

Next, a description will be given of embodiments of the present invention with reference to the drawings. In the following description referring to the drawings, the same or similar reference numerals are assigned to the same or similar portions. However, it should be noted that the drawings are schematic, and that a ratio of thicknesses of respective portions, and the like are different from actual ones. Moreover, as a matter of course, also between the drawings, portions where dimensional relationship and ratio therebetween are different from each other are also included. The embodiments illustrated below are exemplifying a device and a method for embodying the technical idea of this invention, and the embodiments of this invention do not specify materials, shapes, structures, dispositions and the like of constituent components to those described below.

A probe 1 according to the embodiment of the present invention includes: a tubular barrel 10; a rod-shaped first plunger 20 in which a proximal end portion 21 is inserted from a one-side opening end of the barrel 10; and a coil spring 40 disposed inside the barrel 10. The first plunger 20 slides along an axial direction of the barrel 10 in a state in which a distal end is exposed from the opening end of the barrel 10. The coil spring 40 urges the first plunger 20 in the axial direction of the barrel 10.

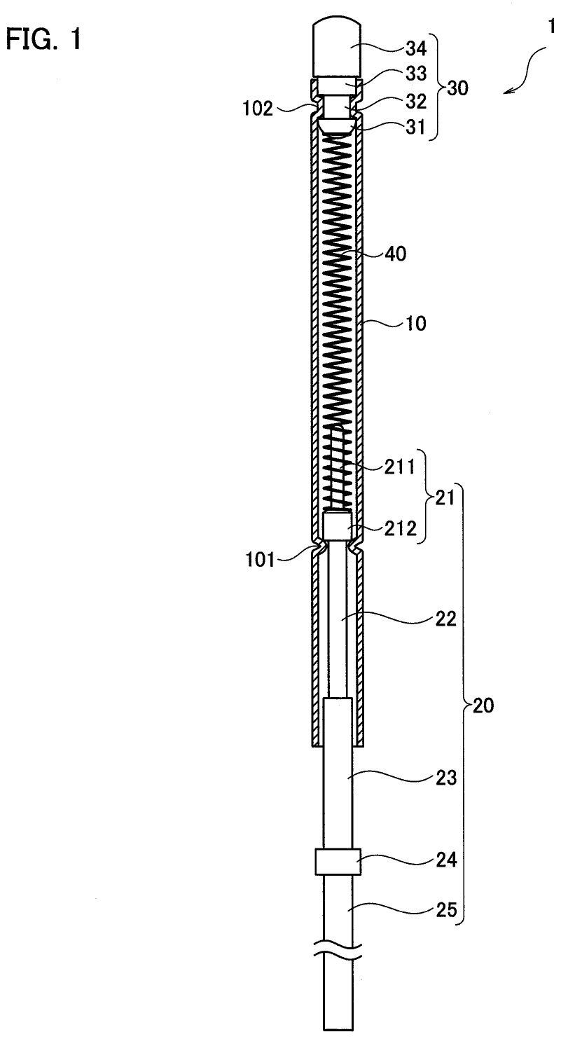

Moreover, the probe 1 includes a rod-shaped second plunger 30 in which a proximal end portion 31 is inserted from other opening end of the barrel 10. The second plunger 30 is joined to the barrel 10 in a state in which a distal end is exposed from the opening end of the barrel 10. One end of the coil spring 40 abuts against the proximal end portion 21 of the first plunger 20, and other end thereof abuts against the proximal end portion 31 of the second plunger 30. In the probe 1 illustrated in FIG. 1, the coil spring 40 urges the first plunger 20 and the second plunger 30 in directions separate from each other.

The first plunger 20 illustrated in FIG. 1 has a configuration in which the proximal end portion 21, a neck portion 22, a first body portion 23, a flange 24 and a second body portion 25 are sequentially coupled to one another. The proximal end portion 21 of the first plunger 20 includes an insertion portion 211, and a head portion 212 coupled to the insertion portion 211. The insertion portion 211 extends inside the coil spring 40 from one end of the coil spring 40. The head portion 212 having a larger outer diameter than an outer diameter of the coil spring 40 abuts against one end of the coil spring 40.

The first plunger 20 is prevented from falling out of the barrel 10 while being prevented from being fixed to the proximal end portion 21 in the inside of the barrel 10. For example, a first junction 101 of the barrel 10 is crimped approximately at a depth at which the head portion 212 of the first plunger 20 does not fall out and the neck portion 22 smaller in diameter than the head portion 212 can pass therethrough. Thus, the neck portion 22 passes through the first junction 101, and the proximal end portion 21 of the first plunger 20 slides inside the barrel 10 without falling out of the barrel 10.

In the inside of the barrel 10, the neck portion 22 is coupled to the first body portion 23 larger in diameter than the neck portion 22. Therefore, in the inside of the barrel 10, the first plunger 20 is supported by two points which are the head portion 212 and the first body portion 23. Thus, an inclination of the first plunger 20 in the inside of the barrel 10 can be suppressed. Moreover, between the first body portion 23 and the second body portion 25, a flange 24 larger in diameter than the first body portion 23 and the second body portion 25 is disposed.

The second plunger 30 illustrated in FIG. 1 has a configuration in which the proximal end portion 31, a neck portion 32, a first body portion 33 and a second body portion 34 are sequentially coupled to one another. The proximal end portion 31 of the second plunger 30 abuts against one end of the coil spring 40 disposed inside the barrel 10.

In a second junction 102, the second plunger 30 is joined to the barrel 10. For example, as illustrated in FIG. 1, the barrel 10 is crimped at a position of the neck portion 32 smaller in diameter than the proximal end portion 31 and the first body portion 33, whereby the second plunger 30 is fixed to the barrel 10. Note that the second plunger 30 and the barrel 10 may be joined to each other by pressure bonding, welding or the like.

As described above, the probe 1 functions as a probe of a one-side sliding type, in which the second plunger 30 is fixed to the barrel 10, and the first plunger 20 slides inside the barrel 10.

At the time of measuring an object to be measured, a distal end of the second body portion 25 of the first plunger 20 connects to the object to be measured, and a distal end of the second body portion 34 of the second plunger 30 connects to a land. Then, between the first plunger 20 and the second plunger 30, an electrical signal propagates through the barrel 10 and the coil spring 40. Therefore, conductive materials are used for the barrel 10, the first plunger 20, the second plunger 30, and the coil spring 40.

For the barrel 10, for example, a conductive metal material such as a nickel (Ni), a nickel alloy, copper (Cu) and a copper alloy is used. Note that an inner wall surface of the barrel 10 may be subjected to a gold plating process. Moreover, for the first plunger 20 and the second plunger 30, for example, a conductive metal material such as a palladium (Pd) alloy and a copper alloy is used. For the coil spring 40, a conductive material such as a hard steel wire, a piano wire and a stainless steel wire is used. The surface of the coil spring 40 may be subjected to a gold plating process.

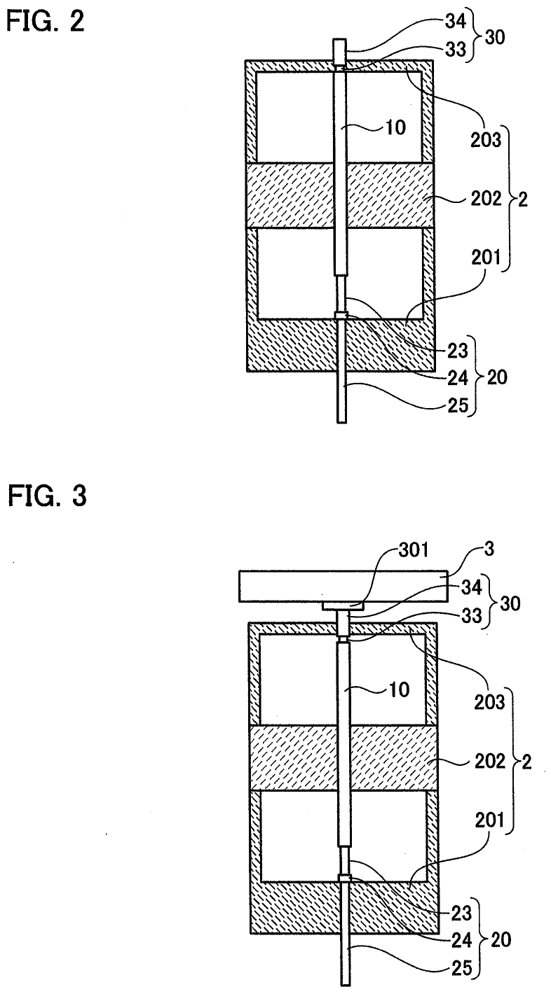

For example, as illustrated in FIG. 2, the probe 1 is held by a probe head 2. That is, the probe head 2 holds the probe 1 in a state in which the probe 1 penetrates a plurality of guide plates which constitute the probe head 2. Ceramics or the like are used for a material of the probe head 2.

The probe head 2 illustrated in FIG. 2 includes a bottom guide plate 201, a middle guide plate 202, and a top guide plate 203. The first plunger 20 penetrates a guide hole of the bottom guide plate 201, and the second plunger 30 penetrates a guide hole of the top guide plate 203. Then, the barrel 10 penetrates a guide hole of the middle guide plate 202 disposed between the bottom guide plate 201 and the top guide plate 203. An outer diameter of the flange 24 is larger than an inner diameter of the guide hole of the bottom guide plate 201, and the flange 24 abuts against the bottom guide plate 201. Thus, the probe 1 is prevented from falling out of the probe head 2.

At the time of the measurement using the probe 1, as illustrated in FIG. 3, a distal end of the second body portion 34 of the second plunger 30 connects to a land 301 of a printed board 3. At this time, a preload for pressing the second plunger 30 against the land 301 is applied to the probe 1 so that the second plunger 30 contacts the land 301 at a constant pressing pressure. By the preload, a portion of the second plunger 30, which is exposed from an upper surface of the probe head 2, is shortened. At this time, the flange 24 of the first plunger 20 is pressed against the bottom guide plate 201, and the coil spring 40 contracts.

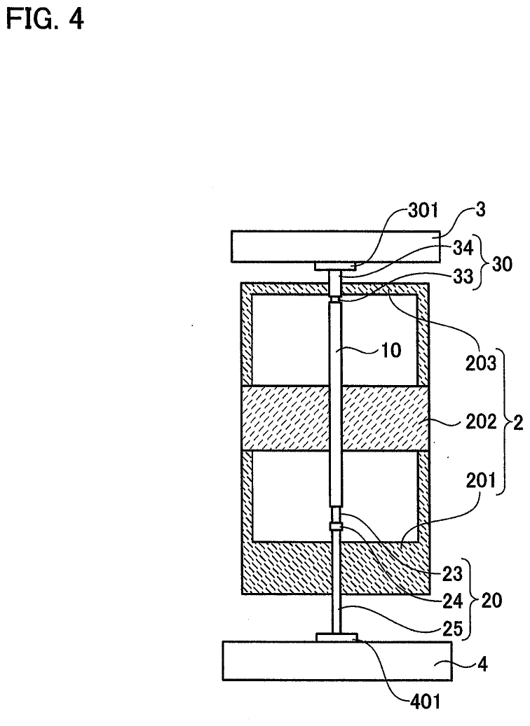

Then, as illustrated in FIG. 4, the distal end of the second body portion 25 of the first plunger 20 connects to an electrode 401 of an object to be measured 4. The object to be measured 4 is a semiconductor device or the like. At this time, an overdrive for pressing the first plunger 20 against the electrode 401 is applied to the probe 1 so that the first plunger 20 contacts the electrode 401 with a predetermined stylus pressure. By the overdrive, the first plunger 20 is pushed into the inside of the barrel 10, and the coil spring 40 contracts.

Specifications of the probe 1 are set so that a maximum stroke amount of the probe 1 is longer than a distance at which the first plunger 20 slides by the preload and the overdrive. Here, “stroke” of the probe 1 is a difference between an overall length of the probe 1 in a state in which the coil spring 40 has a free length and an overall length of the probe 1 in a state in which the coil spring 40 contracts. For example, a total of contracted amounts of the coil spring 40 by the preload and the overdrive is the stroke. Note that the maximum stroke amount is determined by load retention (durability) of the coil spring 40. A maximum value of a stroke amount in which a load is not degraded even if the coil spring 40 repeats expansion and contraction (for example, one million times or more) is the maximum stroke amount.

An electrical signal propagates between the land 301 and the object to be measured 4 through the probe 1. That is, an electrical signal output from the tester is transmitted to the object to be measured 4 via the probe 1, and an electrical signal output from the object to be measured 4 is transmitted to the tester via the probe 1. After the measurement, the probe 1 is separated from the object to be measured 4, whereby the coil spring 40 that has contracted expands.

Incidentally, a pitch of such arranged electrodes of the object to be measured 4 is narrowed, and the number of the electrodes is increased, and so on, whereby such requests as follows are generated for the probe 1.

As the pitch of the arranged electrodes of the object to be measured 4 is narrowed, it is necessary to reduce an outer diameter of the probe 1. For example, when the pitch of the arranged electrodes is 150 μm or less, the outer diameter of the probe 1 is approximately 100 μm. In order to reduce the outer diameter of the probe 1, the outer diameter of the coil spring 40 housed inside the barrel 10 shall also be reduced. Therefore, it is necessary to reduce the wire diameter of the coil spring 40. For example, the outer diameter of the coil spring 40 inserted into the barrel 10 with an outer diameter of approximately 100 μm is approximately 80 μm, and the wire diameter of the coil spring 40 is approximately 20 μm.

However, rigidity of the coil spring 40 decreases as the wire diameter of the coil spring 40 is reduced. Therefore, the coil spring 40 becomes easy to bend in the inside of the barrel 10. As a result, there occurs a negative effect that the coil spring 40 contacts the inside of the barrel 10.

Moreover, the number of electrodes of the object to be measured 4 is increased, and tests for simultaneously testing a plurality of the objects to be measured 4 are made multiple, whereby the number of pins of a probe card is increased. As a negative effect of such a number increase of pins, there increases a total load of such probes 1 arranged on the probe card. Herein, “load” is a pressure when the probe 1 is pressed against the electrode 401 of the object to be measured 4.

For example, when a load of the single probe 1 is 10 gf, a total load of 10000 pieces of the probes 1 is 100 kgf. As the total load of the probes 1 is higher, there increases a pressure applied to the probe card and a member that supports the probe card. Therefore, when the total load of the probe 1 increases, there is a possibility that a variety of test facilities for use in testing the object to be measured 4 will be damaged beyond a load capacity. Moreover, in order to enhance rigidity of the probe card, it becomes necessary to complicate a shape of a structural body thereof or to use an expensive material therefor.

Hence, the probe 1 is required to strike a balance between stable contact between the object to be measured 4 and the probe 1 at a low load and a stroke long enough to absorb variations in the test. Here, “variations” are height variations of bumps of solders or the like when such electrodes 401 of the object to be measured 4 are the bumps, variations of intervals between the electrodes 401 of the object to be measured 4 and the probes 1, the variations being generated by the total load of the probe 1 and caused by the test facilities and a distortion of the probe card, and the like.

As described above, required is the probe 1 that deals with the narrowed pitch of the arranged electrodes of the object to be measured 4 and meets the request for the low load and the long stroke. For example, required is such a probe 1 that deals with 150 μm or less as the pitch of the arranged electrodes and has characteristics in which a load is 7 gf or less and a stroke amount is 400 μm or more. If the load is 7 gf or less, then it becomes easy to suppress the load, which is applied to the test facilities and the probe card, within a range of load capacity. If the stroke amount is 400 μm or more, then an overdrive amount of 300 μm, which is sufficient for the contact between the probe 1 and the electrode 401 of the object to be measured 4, can be ensured in order to suppress a decrease of measurement accuracy.

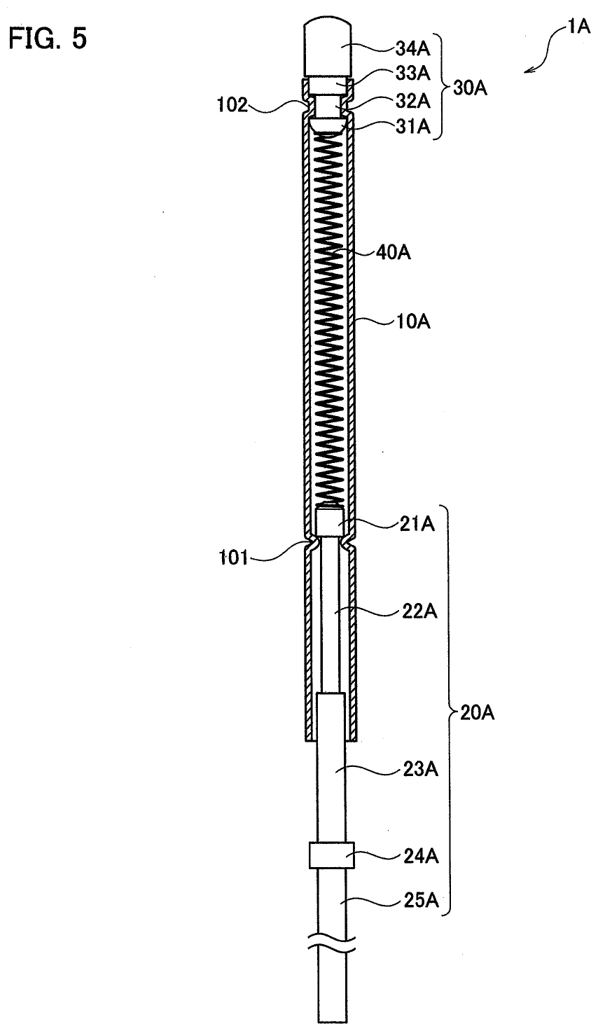

Here, for comparison with the probe 1 illustrated in FIG. 1, a probe 1A of a comparative example, which is illustrated in FIG. 5, is studied. The probe 1A of the comparative example, which is illustrated in FIG. 5, has a configuration in which a coil spring 40A is disposed inside a barrel 10A. A proximal end portion 21A of a first plunger 20A and a proximal end portion 31A of a second plunger 30A abut against end portions of the coil spring 40A in the inside of the barrel 10A. The first plunger 20A slides inside the barrel 10. The second plunger 30A is fixed to the barrel 10A. Note that the proximal end portion 21A of the first plunger 20A does not have a portion that extends in the inside of the coil spring 40.

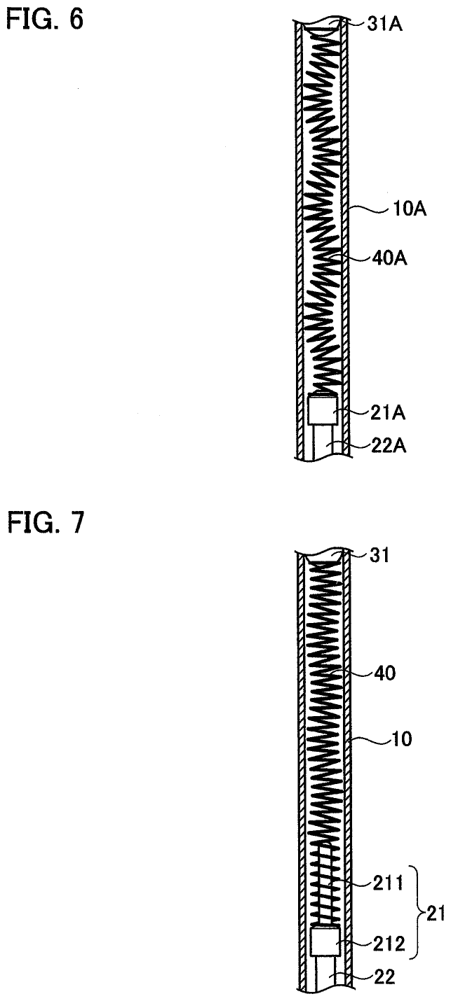

To increase an effective winding number of the coil spring 40A is considered as a method for achieving the low load and the long stroke with regard to the probe 1A of the comparative example. However, a diameter of the coil spring 40A is reduced, and the effective winding number thereof is increased, whereby the coil spring 40 meanders largely when the coil spring 40A contracts in the inside of the barrel 10A as illustrated in FIG. 6. When the coil spring 40A meanders largely, the coil spring 40A and an inner wall surface of the barrel 10A contact each other. As a result, there occurs a problem that the coil spring 40A and the barrel 10A are damaged.

That is, the coil spring 40A strongly rubs against the inner wall surface of the barrel 10A, whereby the surface of the coil spring 40A is scraped, and the inner wall surface of the barrel 10A is peeled off. As a result, an electrical resistance value of the probe 1A increases.

For example, as a result of a probe endurance test in which an overdrive amount is set to 300 μm and the slide of the first plunger 20A is repeated 500 thousand times, the electrical resistance value of the whole of the probe 1A increases to several ten to hundred times that in an initial state. Moreover, the coil spring 40A strongly rubs against the inner wall surface of the barrel 10A by the meandering of the coil spring 40A, whereby the barrel 10A is abraded to sometimes drill a hole in the side surface of the barrel 10A.

Note that the damage of the coil spring 40A and the barrel 10A due to the meandering of the coil spring 40A is prone to occur on a portion of the coil spring 40A, which is close to the first plunger. This results from a difference in slide amount between the following respective portions of the coil spring 40A.

A position where the slide amount of the coil spring 40A is largest is a contact of the coil spring 40A with the first plunger 20A. The slide amount at this contact is equivalent to the overdrive amount. Meanwhile, a position where the slide amount of the coil spring 40A is smallest is a contact of the coil spring 40A with the second plunger 30A, and a slide amount at this contact is zero. Using an overdrive amount OD and an effective winding number n of the coil spring 40A, a slide amount S(i) at a position of an i-th winding number from the contact with the first plunger 20A is substantially represented by the following Equation (1) (1<i≤n):

S(i)=OD−i×(OD/n) Equation (1)

As described above, the slide amount of the coil spring 40A is larger in the portion close to the first plunger. Therefore, the damage of the coil spring 40A and the barrel 10A occurs on the portion close to the first plunger.

In order to suppress the damage of the coil spring 40A and the barrel 10A, which is caused by the slide of the coil spring 40A, also considered are measures for reducing the overdrive amount and the stroke amount. For example, with regard to the probe 1A with a narrow pitch (150 μm or less) and a low load (7 gf or less), the overdrive amount is set to 200 μm, and the maximum stroke amount is set to 300 μm. The overdrive amount and the stroke amount are reduced, whereby an abrasion loss (rubbing distance, rubbing amount) between the coil spring 40A and the inner wall surface of the barrel 10A can be reduced. Thus, the damage of the coil spring 40A and the barrel 10A can be suppressed. However, when the overdrive amount and the stroke amount are reduced, it is difficult to absorb the variations in the test of the object to be measured 4.

In contrast, according to the probe 1 illustrated in FIG. 1, the insertion portion 211 is provided on the proximal end portion 21 of the first plunger 20, whereby the meandering of the coil spring 40 can be suppressed as illustrated in FIG. 7. As a result, damage of the coil spring 40 and the barrel 10 can be suppressed.

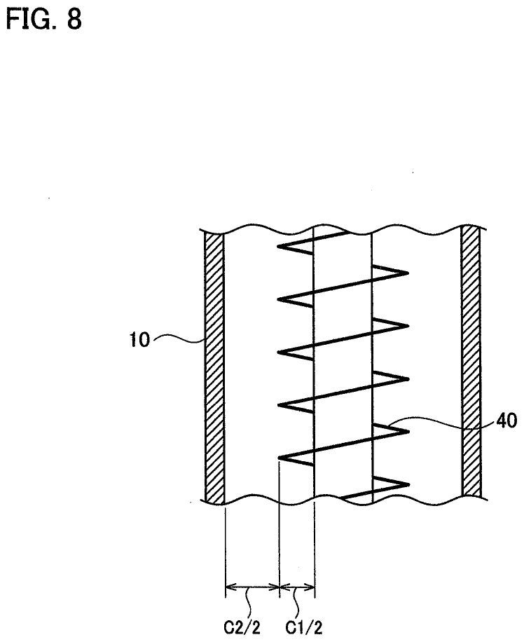

Here, as illustrated in FIG. 8, a difference between an inner diameter of the coil spring 40 and an outer diameter of the insertion portion 211 is defined as a clearance C1, and a difference between an inner diameter of the barrel 10 and the outer diameter of the coil spring 40 is defined as a clearance C2. At this time, it is preferable that the outer diameter of the insertion portion 211 be set so as to establish C1<C2. This is in order to suppress the meandering of the coil spring 40 by reducing the clearance C1, and to suppress the contact between the barrel 10 and the coil spring 40 by increasing the clearance C2 as much as possible.

For example, if the inner diameter of the coil spring 40 is 40 μm when the clearance C2 between the inner diameter of the barrel 10 and the outer diameter of the coil spring 40 is 10 μm, then the outer diameter of the insertion portion 211 is set to 31 μm or more. However, the outer diameter of the insertion portion 211 is set smaller than a minimum diameter of the inner diameter of the coil spring 40, which includes a tolerance.

Moreover, a length of the insertion portion 211 (hereinafter, simply referred to as “length”), which extends inside the coil spring 40, the length going along the axial direction of the barrel 10, is preferably longer in order to suppress the meandering of the coil spring 40. For example, it is preferable that the length of the insertion portion 211 be set equal to or larger than a maximum value of the overdrive amount in order to cover a range where the coil spring 40 contracts by the overdrive.

For example, in the case of a probe 1 in which the maximum value of the overdrive amount is specified to be 300 μm, the length of the insertion portion 211 is set to 300 μm or more. However, the length of the insertion portion 211 is set so that the insertion portion 211 does not contact the proximal end portion 31 of the second plunger 30 when the maximum stroke amount is applied to the probe 1.

Moreover, a size of the head portion 212 of the first plunger 20 is set so as to maintain a stable contact resistance between the head portion 212 and the barrel 10, and to avoid the damage of the inner wall surface of the barrel 10 due to contact thereof with the head portion 212.

Specifically, an outer diameter of the head portion 212 is made larger than an outer diameter of the coil spring 40. For example, when the outer diameter of the coil spring 40 is 80 μm, the outer diameter of the head portion 212 is set to 81 μm or more. However, the outer diameter of the head portion 212 is made smaller than a minimum value of the inner diameter of the barrel 10, which includes a tolerance.

Note that a range where there is a possibility that the coil spring 40 will rub against the inner wall surface of the barrel 10 due to the overdrive corresponds to the overdrive amount. Therefore, when the length of the head portion 212 is shorter than the overdrive amount, it is also considered that the head portion 212 will contact only a region of the inner wall surface of the barrel 10, against which the coil spring 40 rubs. Hence, it is preferable that the length of the head portion 212 be set to the maximum value of the overdrive amount or more. Thus, the head portion 212 also surely contacts such an inner wall surface of the barrel 10 in a region against which the coil spring 40 does not rub. As a result, the contact between the barrel 10 and the first plunger 20 is stabilized, and the contact resistance is also stabilized.

For example, in the case of the probe 1 in which the maximum value of the overdrive amount is specified to be 300 μm, the length of the head portion 212 is set to 300 μm or more. However, the length of the head portion 212 is set within a range where the length of the neck portion 22 can be ensured to be a length of the maximum stroke amount or more. If the length of the neck portion 22 is not the maximum stroke amount or more, then there is a possibility that the first body portion 23 will contact the first junction 101 to hinder the stroke.

As described above, in the probe 1 according to the embodiment, the proximal end portion 21 of the first plunger 20 includes: the insertion portion 211 inserted into the inside of the coil spring 40; and the head portion 212 that is coupled to the insertion portion 211 and abuts against the coil spring 40. In accordance with the probe 1, the meandering of the coil spring 40 at the time of contraction is suppressed. Then, the sizes of the insertion portion 211 and the head portion 212 are set as described above, whereby the damage of the coil spring 40 and the inner wall surface of the barrel 10 can be suppressed. For example, with regard to the probe 1 that deals with the narrow pitch of 150 μm or less and has a load as low as 7 gf or less, a high stroke in which a maximum stroke amount is 450 μm, the high stroke ensuring 300 μm as the maximum value of the overdrive amount, can be achieved.

In accordance with the probe 1, in a probe endurance test in which a slide with an overdrive amount of 300 μm is repeated a million times, an electrical resistance value of the whole of the probe 1 does not fluctuate from an initial state. As described above, the probe 1 in which durability is enhanced can be achieved.

### OTHER EMBODIMENTS

As above, the present invention has been described by the embodiments; however, it should not be understood that the description and the drawings, which form a part of this disclosure, limit the present invention. For those skilled in the art, varieties of alternative embodiments, examples and application technologies will be obvious from this disclosure.

For example, the above illustrates a configuration in which the plungers are inserted into the opening ends on both ends of the barrel 10; however, a configuration in which only the first plunger 20 is inserted into the barrel 10 may be adopted. That is, for the probe 1, such a structure may be adopted, in which the distal end of the first plunger 20 inserted into one end portion of the barrel 10 contacts the object to be measured 4, and other end portion of the barrel 10 contacts the land 301.

As described above, it is natural that the present invention incorporates a variety of embodiments which are not described herein. Hence, the technical scope of the present invention is defined only by items specifying the invention, which are according to the scope of patent claims reasonable based on the above description.

What is claimed is:

1. A probe comprising:
a tubular barrel;
a first plunger that has a proximal end portion inserted from one opening end of the barrel and slides along an axial direction of the barrel in a state in which a distal end is exposed; and
a coil spring that is disposed inside the barrel and urges the first plunger in the axial direction of the barrel,
wherein the proximal end portion of the first plunger includes:
an insertion portion that extends inside the coil spring from one end of the coil spring; and
a head portion that is coupled to the insertion portion, has an outer diameter larger than an outer diameter of the coil spring, and abuts against the one end of the coil spring.

2. The probe according to claim 1, further comprising a second plunger that has a proximal end portion inserted from other opening end of the barrel and is joined to the barrel in a state in which a distal end is exposed,
wherein the coil spring urges the first plunger and the second plunger in directions separate from each other.

3. The probe according to claim 1, wherein a length of the insertion portion that extends inside the coil spring is equal to or more than a maximum value of an overdrive amount applied at a time of measuring an object to be measured.

4. The probe according to claim 1, wherein a length of the head portion that extends along an axial direction of the barrel is equal to or more than a maximum value of an overdrive amount applied at a time of measuring an object to be measured.

5. The probe according to claim 1, wherein a clearance between an inner diameter of the coil spring and an outer diameter of the insertion portion is smaller than a clearance between an inner diameter of the barrel and an outer diameter of the coil spring.
